(19) United States
(12) Patent Application Publication
(10) Pub. No.: US 2026/0190899 A1
(43) Pub. Date: Jul. 2, 2026

(54) SUBSTRATE PROCESSING APPARATUS

(71) Applicant: SEMES CO., LTD., Cheonan-si (KR)

(72) Inventors: Ji Hyeong LEE, Asan-si (KR); Seung Yoon NOH, Cheonan-si (KR); Je Myung CHA, Busan (KR)

(73) Assignee: SEMES CO., LTD., Cheonan-si (KR)

(21) Appl. No.: 19/434,605

(22) Filed: Dec. 29, 2025

(30) Foreign Application Priority Data
Dec. 30, 2024 (KR) 10-2024-0200446

(51) Int. Cl. H10P 72/00; H10P 72/76

(52) U.S. Cl. CPC H10P 72/0402; H10P 72/7618

(57) ABSTRACT

The substrate processing apparatus includes: a chamber body having an inner space; a cup placed in the inner space and having a treatment space with an open top; a spin chuck for supporting the substrate in the treatment space; a liquid supply unit for supplying a treatment liquid to the substrate supported by the spin chuck; a fan unit for providing descending airflow to the inner space; an exhaust pipe for exhausting atmosphere in the inner space; and an airflow adjustment unit for controlling a flow of the descending airflow supplied from the fan unit, in which the airflow adjustment unit includes: an airflow adjustment plate provided in a first mode or a second mode to control a flow of descending airflow supplied from the fan unit; and a driver for driving the airflow adjustment plate so that the airflow adjustment plate is provided in the first mode or the second mode.

### CROSS-REFERENCE TO RELATED APPLICATION

This application claims priority to and the benefit of Korean Patent Application No. 10-2024-0200446 filed in the Korean Intellectual Property Office on Dec. 30, 2024, the entire contents of which are incorporated herein by reference.

### TECHNICAL FIELD

The present invention relates to an apparatus for processing a substrate, and more particularly, to an apparatus for processing a substrate by supplying a treatment liquid to the substrate.

### BACKGROUND ART

In order to manufacture a semiconductor device or a liquid crystal display, various processes, such as photolithography, ashing, etching, ion implantation, thin film deposition, and cleaning, for a substrate may be performed. Among them, the cleaning process is a process for removing particles remaining on the substrate, and is performed before and after each process.

This cleaning process is applied differently depending on the surface properties of the substrate. In particular, in the case of hydrophobizing the surface of the substrate or washing the hydrophobized surface, a chemical treatment operation and a rinse treatment operation are performed. The substrate may be supplied with chemical while being rotated, and a rinse liquid, such as isopropyl alcohol, may be supplied thereafter.

When the cleaning process is performed, it is necessary to maintain a high or low pressure around a treatment space in which the substrate is processed according to each operation. The pressure around the treatment space was adjusted by supplying a descending airflow into the chamber through an existing Fan Filter Unit (FFU). In the pressure adjustment through the fan filter unit, it is difficult to control the pressure for each area of the inner space of the chamber, and in some cases, a dead zone may be generated or fume or chemical liquid may leak out from the treatment space.

### SUMMARY OF THE INVENTION

The present invention has been made in an effort to provide a substrate processing method capable of minimizing the generation of a dead zone during a cleaning process.

The present invention has also been made in an effort to provide a substrate processing apparatus capable of minimizing the scattering of a chemical solution or diffusion of fume during a cleaning process.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a chamber body having an inner space; a cup placed in the inner space and having a treatment space with an open top; a spin chuck for supporting the substrate in the treatment space; a liquid supply unit for supplying a treatment liquid to the substrate supported by the spin chuck; a fan unit for providing descending airflow to the inner space; an exhaust pipe for exhausting atmosphere in the inner space; and an airflow adjustment unit for controlling a flow of the descending airflow supplied from the fan unit, wherein the airflow adjustment unit includes: an airflow adjustment plate provided in a first mode or a second mode to control a flow of descending airflow supplied from the fan unit; and a driver for driving the airflow adjustment plate so that the airflow adjustment plate is provided in the first mode or the second mode, and in the first mode, the airflow adjustment plate may be configured to further diffuse the descending airflow discharged from the fan unit in the inner space than the airflow adjustment plate in the second mode.

According to the exemplary embodiment of the present invention, wherein in the second mode, the airflow adjustment plate is configured to further concentrate the descending airflow discharged from the fan unit in the treatment space than the airflow adjustment plate in the first mode.

According to the exemplary embodiment of the present invention, wherein the driver rotates the airflow adjustment plate so that the airflow adjustment plate may be position-changed between the first mode and the second mode.

According to the exemplary embodiment of the present invention, wherein the fan unit includes a polygonal bottom plate through which airflow is discharged, the airflow adjustment plates are provided at positions corresponding to sides of the bottom plate, respectively, and each of the airflow adjustment plates may be rotatably provided with an axis parallel to each of the corresponding sides as a rotation axis.

According to the exemplary embodiment of the present invention, wherein in the first mode, the airflow adjustment plate may be inclined further downward in a direction toward an inner wall of the chamber body than the airflow adjustment plate in the second mode.

According to the exemplary embodiment of the present invention, wherein in the first mode, an angle between the airflow adjustment plate and the bottom plate is an obtuse angle, and in the second mode, an angle between the airflow adjustment plate and the bottom plate may be a right angle or an acute angle.

According to the exemplary embodiment of the present invention, wherein the airflow adjustment unit may be coupled to the bottom plate.

According to the exemplary embodiment of the present invention, wherein when viewed from above, the airflow adjustment unit may be coupled to an upper wall of the chamber body at a position adjacent to the bottom plate.

According to the exemplary embodiment of the present invention, wherein a perforated plate is provided below the fan unit in the inner space, and the airflow adjustment unit may be coupled to the perforated plate.

According to the exemplary embodiment of the present invention, wherein the liquid supply unit includes: a first liquid supply unit for supplying a first liquid; a second liquid supply unit for supplying a second liquid different from the first liquid; and a controller, and the controller may be configured to control the liquid supply unit so that a first liquid treatment operation of processing the substrate by supplying the first liquid and a second liquid treatment operation of processing the substrate by supplying the second liquid are sequentially performed, and control the driver so that the airflow adjustment plate maintains a first mode during the first liquid treatment operation and the airflow adjustment plate maintains a second mode during the second liquid treatment operation.

According to the exemplary embodiment of the present invention, wherein the first liquid is a liquid that does not contain an acid component, and the second liquid may be a liquid that contains an acid component.

According to the exemplary embodiment of the present invention, wherein the fan unit includes: a normal mode in which the first gas is supplied in the descending airflow during the liquid treatment of the substrate; and a low humidity mode in which second gas having a lower humidity than the first gas is supplied in the descending airflow during the liquid treatment of the substrate, and the airflow adjustment plate is provided in the first mode in the normal mode and may be provided in the second mode in the low humidity mode.

According to the exemplary embodiment of the present invention, comprising:
a first processing operation of processing the substrate while rotating the substrate at a first speed, and a second processing operation of processing the substrate while rotating the substrate at a second speed slower than the first speed, wherein the airflow adjustment plate is provided in the first mode in the first processing operation and may be provided in the second mode in the second processing operation.

An exemplary embodiment of the present disclosure, an apparatus for processing a substrate, the apparatus comprising: a chamber body having an inner space; a cup placed in the inner space and having a treatment space with an open top; a spin chuck for supporting the substrate in the treatment space; a liquid supply unit for supplying a treatment liquid to the substrate supported by the spin chuck; a fan unit for providing descending airflow to the inner space; an exhaust pipe for exhausting atmosphere in the inner space; and an airflow adjustment unit for controlling a flow of descending airflow supplied from the fan unit, wherein the airflow adjustment unit may include: an airflow adjustment plate disposed between the fan unit and the cup and controlling a flow of descending airflow supplied from the fan unit; and a driver for rotating the airflow adjustment plate so that an angle between a bottom plate of the fan unit and the airflow adjustment plate is changed.

According to the exemplary embodiment of the present invention, wherein the bottom plate is provided in a rectangular shape including four sides, the airflow adjustment plate is disposed on each of the four sides, and each of the airflow adjustment plates may be rotatably provided with an axis parallel to the corresponding side of the four sides as a rotation axis.

According to the exemplary embodiment of the present invention, wherein the airflow adjustment unit may be coupled to the fan unit.

According to the exemplary embodiment of the present invention, wherein the airflow adjustment unit may be coupled to an upper wall of the chamber body.

According to the exemplary embodiment of the present invention, further comprising: perforated plate, wherein the airflow adjustment unit may be coupled to a lower surface of the perforated plate.

An exemplary embodiment of the present disclosure, an apparatus for processing a substrate, the apparatus comprising: a chamber body having an inner space; a cup placed in the inner space and having a treatment space with an open top; a spin chuck for supporting the substrate in the treatment space; a liquid supply unit for supplying a treatment liquid to the substrate supported by the spin chuck; a fan unit for providing descending airflow to the inner space; an exhaust pipe for exhausting atmosphere in the inner space; and an airflow adjustment unit for controlling a flow of descending airflow supplied from the fan unit, wherein the airflow adjustment unit includes: an airflow adjustment plate provided in a first mode or a second mode to control a flow of descending airflow supplied from the fan unit; and a driver for driving the airflow adjustment plate so that the airflow adjustment plate is provided in the first mode or the second mode, and in the first mode, the airflow adjustment plate is configured to further diffuse the descending airflow discharged from the fan unit in the inner space than the airflow adjustment plate in the second mode, in the second mode, the airflow adjustment plate is configured to further concentrate the descending airflow discharged from the fan unit in the treatment space than the airflow adjustment plate in the first mode, the driver rotates the airflow adjustment plate so that the airflow adjustment plate is position-changed between the first mode and the second mode, the fan unit includes a polygonal bottom plate through which airflow is discharged, the airflow adjustment plates are provided at positions corresponding to sides of the bottom plate, respectively, each of the airflow adjustment plates is rotatably provided with an axis parallel to each of the corresponding sides as a rotation axis, and in the first mode, the airflow adjustment plate is inclined further downward in a direction toward an inner wall of the chamber body than the airflow adjustment plate in the second mode.

According to the exemplary embodiment of the present invention, wherein the liquid supply unit includes: a first liquid supply unit for supplying a first liquid; a second liquid supply unit for supplying a second liquid different from the first liquid; and a controller, and the controller may be configured to control the liquid supply unit so that a first liquid treatment operation of processing the substrate by supplying the first liquid and a second liquid treatment operation of processing the substrate by supplying the second liquid are sequentially performed, and control the driver so that the airflow adjustment plate maintains a first mode during the first liquid treatment operation and the airflow adjustment plate maintains a second mode during the second liquid treatment operation, and the first liquid is a liquid that does not contain an acid component, and the second liquid may be a liquid that contains an acid component.

According to the exemplary embodiment of the present invention, it is possible to minimize the generation of a dead zone during a cleaning process.

According to the exemplary embodiment of the present invention, it is possible to minimize the scattering of a chemical solution or diffusion of fume during a cleaning process.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a top plan view of a process chamber according to an embodiment of the present invention as viewed from the front.

FIG. 3 is a top plan view of the process chamber of FIG. 2 viewed from below.

FIGS. 4 to 5 are diagrams illustrating a substrate processing method according to an embodiment of the present invention.

FIGS. 6 to 8 are diagrams illustrating a substrate processing method according to another embodiment of the present invention.

FIGS. 9 to 10 are diagrams illustrating a substrate processing method according to still another embodiment of the present invention.

FIG. 11 is a plan view of a process chamber according to another embodiment of the present invention as viewed from the front.

FIG. 12 is a top plan view of a process chamber according to still another embodiment of the present invention as viewed from the front.

FIG. 13 is a top plan view of the process chamber of FIG. 12 viewed from below.

### DETAILED DESCRIPTION

Hereinafter, exemplary embodiments of the present invention will be described in more detail with reference to the accompanying drawings. The exemplary embodiments of the present invention may be modified in various forms, and the scope of the present invention should not be construed as being limited to the exemplary embodiments described below. The present exemplary embodiment is provided to more completely describe the present invention to a person having average knowledge in the art. Therefore, the shapes of components in the drawings are exaggerated to emphasize a clearer description.

In the present exemplary embodiment, the present invention will be described based on a process of liquid-treating a substrate by supplying a liquid, such as a cleaning liquid, onto the substrate as an example. However, the present exemplary embodiment is not limited to the cleaning process, but is applicable to various processes of treating the substrate using a treatment liquid, such as an etching process, an ashing process, and a developing process.

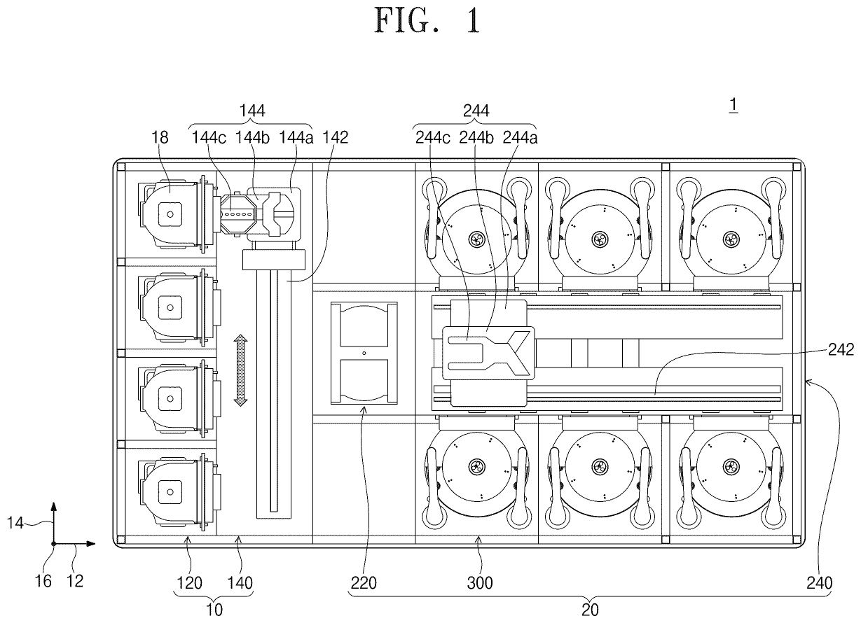

FIG. 1 is a plan view schematically illustrating a substrate processing apparatus according to an exemplary embodiment of the present invention.

Referring to FIG. 1, a substrate treating apparatus 1 includes an index module 10 and a process module 20. The index module 10 includes a load port 120 and a transfer frame 140. The load port 120, the transfer frame 140, and the process module 20 are sequentially arranged in a line. Hereinafter, a direction in which the load port 120, the transfer frame 140, and the process module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A container 130 in which the substrate W is accommodated is seated on the load port 120. A plurality of load ports 120 is provided, and they are arranged in a line along the second direction 14. The number of load ports 120 may increase or decrease depending on the process efficiency, the foot print condition, and the like of the process module 20. A plurality of slots (not shown) for accommodating the substrates W in a state in which the substrates are horizontally arranged with respect to the ground is formed in the container 130. A Front Open Integrated Pod (FORUP) is used as the container 130.

The process module 20 includes a buffer unit 220, a transfer chamber 240, and a process chamber 300. A longitudinal direction of the transfer chamber 240 is disposed parallel to the first direction 12. Process chambers 300 are disposed on both sides of the transfer chamber 240, respectively. The process chambers 300 are provided to be symmetrical with respect to the transfer chamber 240 on one side and the other side of the transfer chamber 240. A plurality of process chambers 300 is provided on one side of the transfer chamber 240. Some of the process chambers 300 are disposed along the longitudinal direction of the transfer chamber 240. In addition, some of the process chambers 300 are arranged to be stacked on each other. That is, the process chambers 260 are disposed on one side of the transfer chamber 240 in an arrangement of A×B. Herein, A is the number of process chambers 300 provided in a row along the first direction 12, and B is the number of process chambers 300 provided in a row along the third direction 16. When four or six process chambers 300 are provided on one side of the transfer chamber 240, the process chambers 300 are disposed in a 2×2 or 3×2 arrangement. The number of process chambers 300 may increase or decrease. Unlike the above description, the process chamber 300 is provided only to one side of the transfer chamber 240. In addition, the process chambers 300 are provided as a single layer on one side and opposite sides of the transfer chamber 240.

The buffer unit 220 is disposed between the transfer frame 140 and the transfer chamber 240. The buffer unit 220 provides a space in which the substrate W stays before the substrate W is transferred between the transfer chamber 240 and the transfer frame 140. A slot (not shown) in which the substrate W is placed is provided in the buffer unit 220. A plurality of slots (not shown) is provided to be spaced apart from each other along a third direction 16. The buffer unit 220 opens the surface facing the transfer frame 140 and the surface facing the transfer chamber 240.

The transfer frame 140 transfers the substrate W between the container 130 seated on the load port 120 and the buffer unit 220. An index rail 142 and an index robot 144 are provided in the transfer frame 140. The longitudinal direction of the index rail 142 is provided in parallel to the second direction 14. The index robot 144 is installed on the index rail 142 and moves linearly in the second direction 14 along the index rail 142. The index robot 144 has a base 144a, a body 144b, and an index arm 144c. The base 144a is installed to be movable along the index rail 142. The body 144b is coupled to the base 144a. The body 144b is provided on the base 144a to be movable along the third direction 16. In addition, the body 144b is provided to be rotatable on the base 144a. The index arm 144c is coupled to the body 144b and is provided to be able to move forward and backward with respect to the body 144b. A plurality of index arms 144c is provided to be individually driven. The index arms 144c are disposed to be stacked while being spaced apart from each other along the third direction 16. Some of the index arms 144c are used to transfer the substrate W from the process module 20 to the container 130, and another some thereof is used to transfer the substrate W from the container 130 to the process module 20. This prevents particles generated from the substrate W before the process processing in the process in which the index robot 144 loads and unloads the substrate W from adhering to the substrate W after the process processing.

The transfer chamber 240 transfers the substrate W between the buffer unit 220 and the process chamber 300 and between the process chambers 300. A guide rail 242 and a main robot 244 are provided in the transfer chamber 240. The guide rail 242 is arranged such that its longitudinal direction is parallel to the first direction 12. The main robot 244 is installed on the guide rail 242, and moves linearly along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided on the base 244a to be movable along the third direction 16. Furthermore, the body 244b is provided on the base 244a to be rotatable on the base 244a. The main arm 244c is coupled to the body 244b, which is provided to be movable forward and backward with respect to the body 244b. A plurality of index arms 244c is provided to be individually driven. The main arms 244c are arranged to be stacked while being spaced apart from each other along the third direction 16.

The process chamber 300 may be a liquid treating chamber for performing a liquid treatment process by supplying a liquid to the substrate W. For example, the liquid treating process may be a cleaning process for cleaning a substrate with a cleaning liquid. Chemical treatment, rinsing treatment, and drying treatment are all performed on the substrate in the process chamber. Optionally, a drying chamber for drying the substrate may be provided separately from the liquid treating chamber.

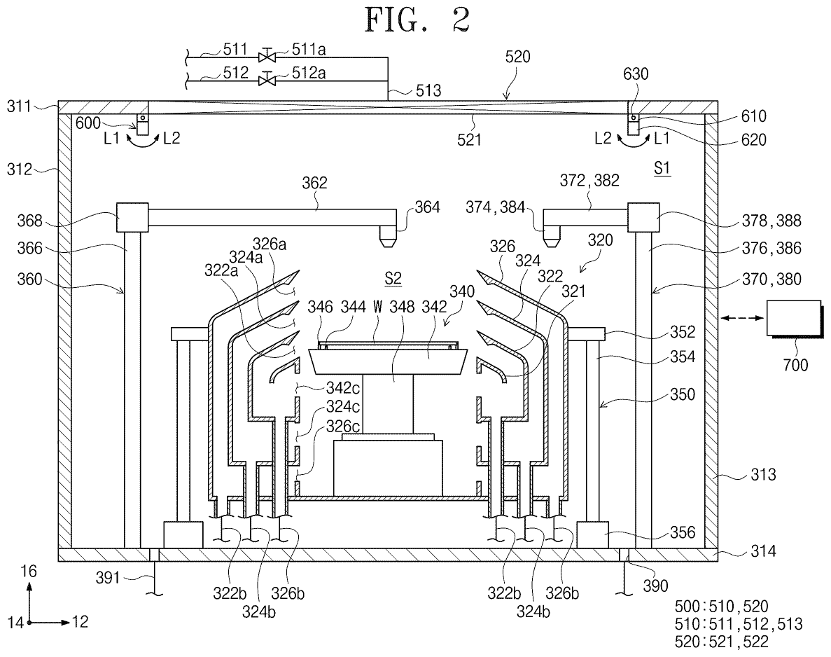

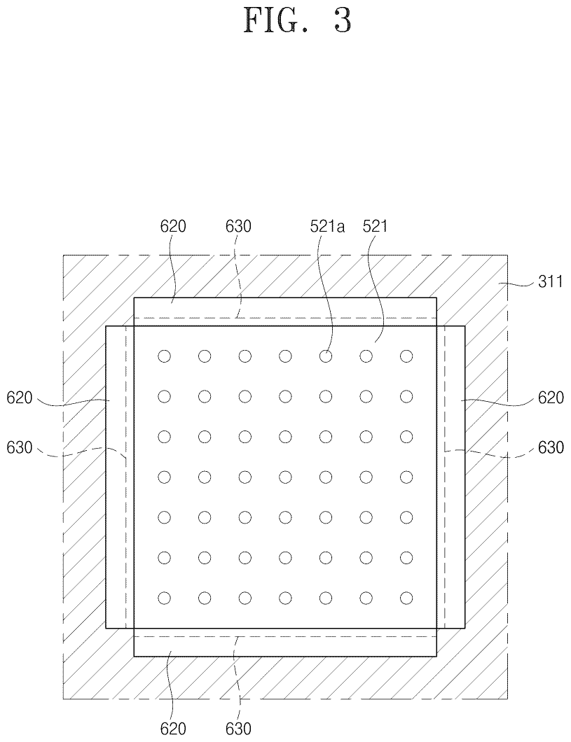

FIG. 2 is a top plan view of the process chamber according to the embodiment of the present invention as viewed from the front. FIG. 3 is a top plan view of the process chamber of FIG. 2 viewed from below.

Referring to FIGS. 2 to 3, the process chamber 300 includes a chamber body 310, a cup 320, a spin chuck 340, a lifting unit 350, a first liquid supply unit 360, a second liquid supply unit 370, an exhaust pipe 390, a fan unit 500, an airflow adjustment unit 600, and a controller 700.

The chamber body 310 forms an inner space S1. The chamber body 310 has an upper wall 311, sidewalls 312, 313, and a bottom wall 314, and the inner space S1 is a space defined by the sidewalls 312 and 313 and the bottom wall 314. According to an example, the chamber body 310 generally has a rectangular parallelepiped shape and has a first sidewall 312 and a second sidewall 313. The first sidewall 312 is located opposite to the second sidewall 313.

The cup 320 is located in the inner space S1. The cup 320 has a treatment space S2 for processing the substrate W. An upper portion of the treatment space S2 is opened. The cup 320 includes a guide wall 321, an inner recovery container 322, a middle recovery container 324, and an outer recovery container 326. Each of the recovery containers 322, 324, and 326 separates and recovers different treatment liquids from the treatment liquids used in the process. The guide wall 321 is provided in an annular ring shape surrounding the spin chuck 340, and the inner recovery container 322 is provided in an annular ring shape surrounding the guide wall 321. The middle recovery container 324 is provided in an annular ring shape surrounding the inner recovery container 322, and the outer recovery container 326 is provided in an annular ring shape surrounding the middle recovery container 324. The space 322a between the inner recovery container 322 and the guide wall 321 functions as a first inlet through which the treatment liquid is introduced. The space 324a between the inner recovery container 322 and the middle recovery container 324 functions as a second inlet through which the treatment liquid is introduced. The space 326a between the middle recovery container 324 and the outer recovery container 326 functions as a third inlet through which the treatment liquid is introduced. Further, the space 322c between a lower end of the guide wall 321 and the inner recovery container 322 functions as a first outlet through which fume and airflow generated from the treatment liquid are discharged. The space 324c between a lower end of the inner recovery container 322 and the middle recovery container 324 functions as a second outlet through which fume and airflow generated from the treatment liquid are discharged. The space 326c between a lower end of the intermediate recovery container 324 and the outer recovery container 326 functions as a third outlet through which fume and airflow generated from the treatment liquid are discharged. Different types of treatment liquid are introduced into the recovery container, respectively. The recovery containers 322, 324, and 326 are connected with recovery lines 322b, 324b, and 326b extending vertically in a direction below the bottom surface thereof, respectively. The recovery lines 322b, 324b, and 326b discharges the treatment liquid, fume, and airflow introduced through the recovery containers 322, 324, and 326, respectively. The discharged treatment liquid is reused through an external treatment liquid regeneration system (not shown).

The spin chuck 340 supports the substrate W and rotates the substrate W during the process. The spin chuck 340 includes a spin chuck 342, a support pin 344, a chuck pin 346, a support shaft 348, and a driving unit (not shown). The spin chuck 342 has an upper surface that is provided in a generally circular shape when viewed from the top. The support shaft 348 is fixedly coupled to a bottom surface of the spin chuck 342, and the support shaft 348 is rotatably provided by a driving unit.

A plurality of support pins 344 is provided. The support pins 344 are disposed on the edge portion of the upper surface of the spin chuck 342 to be spaced apart from each other by a predetermined interval and protrude upward from the spin chuck 342. The support pin 344 supports the rear edge of the substrate W so that the substrate W is spaced apart from the upper surface of the spin chuck 342 by a predetermined distance.

A plurality of chuck pins 346 is provided. The chuck pin 346 is disposed to be farther from the center of the spin chuck 342 than the support pin 344. The chuck pin 346 is provided to protrude upward from the spin chuck 342. The chuck pin 346 supports a side portion of the substrate W so as not to be separated from a regular position in a lateral direction when the substrate W is rotated. The chuck pin 346 is provided to be able to move linearly between a standby position and a support position along a radial direction of the spin chuck 342. The standby position is a position farther from the center of the spin chuck 342 than the support position. When the substrate W is loaded on or unloaded from the spin chuck 340, the chuck pin 346 is located at the standby position, and when the process is performed on the substrate W, the chuck pin 346 is located at the support position. At the support position, the chuck pin 346 is in contact with the side portion of the substrate W.

The lifting unit 350 linearly moves the cup 320 in the up and down direction. As the cup 320 is moved up and down, a relative height of the cup 320 with respect to the spin head of the spin chuck 340 is changed. The lifting unit 350 includes a bracket 352, a moving shaft 354, and a driver 356. The bracket 352 is fixedly installed on the outer wall of the cup 320, and the moving shaft 352 that is moved in the up and down direction by the driver 356 is fixedly coupled to the bracket 354. When the substrate W is placed on the spin head of the spin chuck 340 or lifted from the spin head of the spin chuck 340, the cup 320 is lowered so that the spin head of the spin chuck 340 protrudes upward from the cup 320. Also, when the process is performed, the height of the cup 320 is adjusted so that the treatment liquid may be introduced into a preset recovery container according to the type of treatment liquid supplied to the substrate W. Selectively, the lifting unit 350 may move the spin head of the spin chuck 340 in the vertical direction.

The first liquid supply unit 360 supplies a first liquid onto the substrate W, and the second liquid supply unit 370 supplies a second liquid onto the substrate W. The first liquid may be a liquid that does not contain an acid component, the second liquid may be a liquid that does not contain an acid component, and the third liquid may be an organic solvent. For example, the first liquid may include pure water, the second liquid may be a Sulfuric Acid Peroxide Mixture (SPM) or a Hydrofluoric Acid (HF), and the third liquid may be Isopropyl alcohol (IPA).

The first liquid supply unit 360 includes a first support shaft 366, a first arm 362, a first driver 368, and a first nozzle 364. The first support shaft 366 is located at one side of the cup 320. The first support shaft 366 has a rod shape of which a longitudinal direction thereof faces a third direction 16. The first support shaft 366 is provided to be rotatable by the first driver 368. The first arm 362 is coupled to an upper end of the first support shaft 366. The first arm 362 vertically extends from the first support shaft 366. The first nozzle 364 is fixedly coupled to an end of the first arm 362. As the first support shaft 366 is rotated, the first nozzle 364 is capable of swing and moving together with the first arm 362. The first nozzle 364 is swing-moved and moved to a process position and a standby position. Here, the process position is a position where the first nozzle 364 is opposite to the substrate W supported by the spin chuck 340, and the standby position is a position where the first nozzle 364 is out of the process position.

The second liquid supply unit 370 and the third liquid supply unit 380 may be configured in the same manner as the first liquid supply unit 360.

The exhaust pipe 400 is installed on the bottom wall 314 of the chamber body 310. The exhaust pipe 390 exhausts the atmosphere of the inner space S1. The atmosphere of the inner space S1 may include at least one of first gas, second gas, the first liquid, and the second liquid to be described below.

The fan unit 500 may supply descending airflow to the inner space S1. The fan unit 500 includes a gas supply line 510 and a fan filter 520.

The gas supply line 510 includes a first supply line 511, a second supply line 512, and a main supply line 513.

The first supply line 511 may supply first gas to the inner space S1. The first gas may be air. An opening/closing valve 421a may be installed in the first supply line 421 to adjust a flow rate of the first gas flowing through the flow path therein or to open and close the internal flow path thereof.

The second supply line 512 may supply second gas to the inner space S1. The second gas may be low humidity air (CDA) having a humidity lower than that of the first gas. An opening/closing valve 422a may be installed in the second supply line 422 to adjust a flow rate of the second gas flowing through the flow path therein or to open and close the internal flow path thereof. An opening/closing valve 422b for opening and closing the internal flow path of the second supply line 422 may be installed in the second supply line 422. A first supply line 511 and a second supply line 512 are connected to the main supply line 513. The main supply line 513 supplies the gas supplied from the first supply line 511 or the second supply line 512 to the internal space S1.

The fan filter 520 is installed on the upper wall 311 of the chamber body 310. The fan filter 520 is connected to the gas supply line 510. The fan filter 520 receives the first gas or the second gas from the main supply line 513. The fan filter 520 filters the first gas or the second gas to generate descending airflow. The fan filter 520 supplies descending airflow to the inner space S1. The fan filter 520 supplies descending airflow through a hole 521a formed in a bottom plate 521. Although the bottom plate 521 is shown as having a quadrangular shape, unlike this, the bottom plate 521 may have a polygonal shape other than the quadrangular shape.

The airflow adjustment unit 600 may control the flow of descending airflow supplied from the fan unit 500. The airflow adjustment unit 600 may include a plurality of drivers 610 and a plurality of airflow adjustment plates 620. Meanwhile, in the drawing, four drivers 610 and four airflow adjustment plates 620 are shown, respectively, as the plurality of drivers 610 and the plurality of airflow adjustment plates 620, but this is illustrative, and the present invention is not limited thereto. For example, when the bottom plate 521 has a polygonal shape other than a square shape, the plurality of drivers 610 and the plurality of airflow adjustment plates 620 may be provided in the same number as the number of sides of the bottom plate 521.

The plurality of drivers 610 is installed on the upper wall 311 of the chamber body 310. When viewed from above, the plurality of drivers 610 is provided at positions corresponding to the respective sides of the bottom plate 521 of the fan filter 520. The plurality of drivers 610 may drive the plurality of corresponding airflow adjustment plates 620 to change the positions of the plurality of corresponding airflow adjustment plates 620. The plurality of drivers 610 may change the positions of the plurality of corresponding airflow adjustment plates 620 by rotating the plurality of corresponding airflow adjustment plates 620 through the corresponding rotation shafts 630, respectively. The rotation shaft 630 may be parallel to any one of the four sides of the bottom plate 531, and any one of the four sides of the bottom plate 531 may be a side corresponding to the airflow adjustment plate 520 rotated through the rotation shaft 630.

When viewed below, the plurality of airflow adjustment plates 620 is provided at positions corresponding to the sides of the bottom plate 521, respectively, and the plurality of airflow adjustment plates 620 may surround the bottom plate 521. Although the plurality of airflow adjustment plates 620 is illustrated to have a substantially rectangular shape, this is an example and the present invention is not limited thereto.

The plurality of airflow adjustment plates 620 may be hinge-coupled to the plurality of corresponding drivers 610, respectively. The plurality of airflow adjustment plates 620 may be rotated by the plurality of drivers 610 with respect to the rotation shaft 630, and accordingly, positions thereof may be changed.

The plurality of airflow adjustment plates 620 may be provided in a first mode by rotating in a first direction d1 by the plurality of drivers 610, or may be provided in a second mode by rotating in a second direction d2. The first mode may be a mode for diffusing the descending airflow supplied by the fan filter 520 into the inner space S1, and the second mode may be a mode for concentrating the descending airflow supplied by the fan filter 520 in the treatment space S2. The first direction d1 may be a direction toward the sidewalls 312 and 313 of the chamber body 310, and the second direction d2 may be a direction toward the fan filter 520.

When the plurality of airflow adjustment plates 620 is provided in the first mode, the plurality of airflow adjustment plates 620 may be positioned to be inclined further downward in the first direction d1 than when the plurality of airflow adjustment plates 620 is provided in the second mode. When the plurality of airflow adjustment plates 620 is provided in the first mode, the angle between each of the plurality of airflow adjustment plates 620 and the bottom plate 521 may be an obtuse angle, and when the plurality of airflow adjustment plates 620 is provided in the second mode, the angle between each of the plurality of airflow adjustment plates 620 and the bottom plate 521 may be a right angle or an acute angle.

The controller 700 may control the cup 320, the spin chuck 340, the lifting unit 350, the first liquid supply unit 360, the second liquid supply unit 370, the third liquid supply unit 380, the exhaust pipe 400, the fan unit 500, and the airflow adjustment unit 600.

The controller 700 may control the spin chuck 340, the first liquid supply unit 360, the second liquid supply unit 370, the third liquid supply unit 380, the exhaust pipe 400, the fan unit 500, and the airflow adjustment unit 600 so that a first liquid treatment operation and a second liquid treatment operation are sequentially performed.

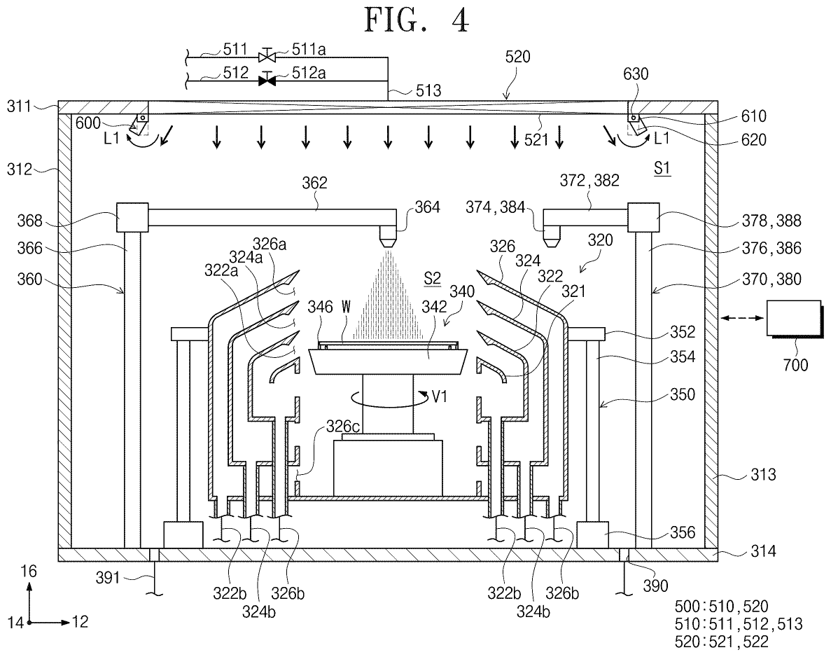

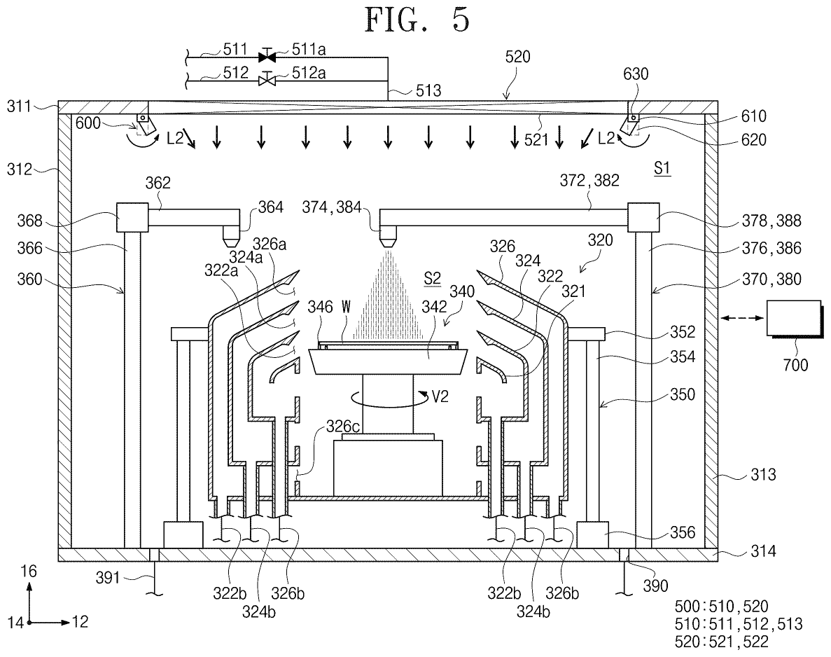

FIGS. 4 to 5 are diagrams illustrating a substrate processing method according to an embodiment of the present invention.

Referring to FIGS. 4 to 5, the controller 700 controls the airflow adjustment unit 600 based on a rotational speed of the substrate when processing the substrate W. A substrate processing operation includes a first processing operation and a second processing operation.

The first processing operation is an operation of processing the substrate by supplying the liquid to the substrate while rotating the substrate W at a first speed V1, and the second processing operation is an operation of processing the substrate by supplying the liquid to the substrate while rotating the substrate at a second speed V2. The second speed V2 may be faster than the first speed V2. In the first processing operation, the first liquid may be supplied onto the substrate W, and in the second processing operation, the second liquid or the third liquid may be supplied onto the substrate W. The controller 700 may control the airflow adjustment unit 600 so that the airflow adjustment plate 620 may be provided in the first mode in the first processing operation, and the airflow adjustment plate 620 may be provided in the second mode in the second processing operation.

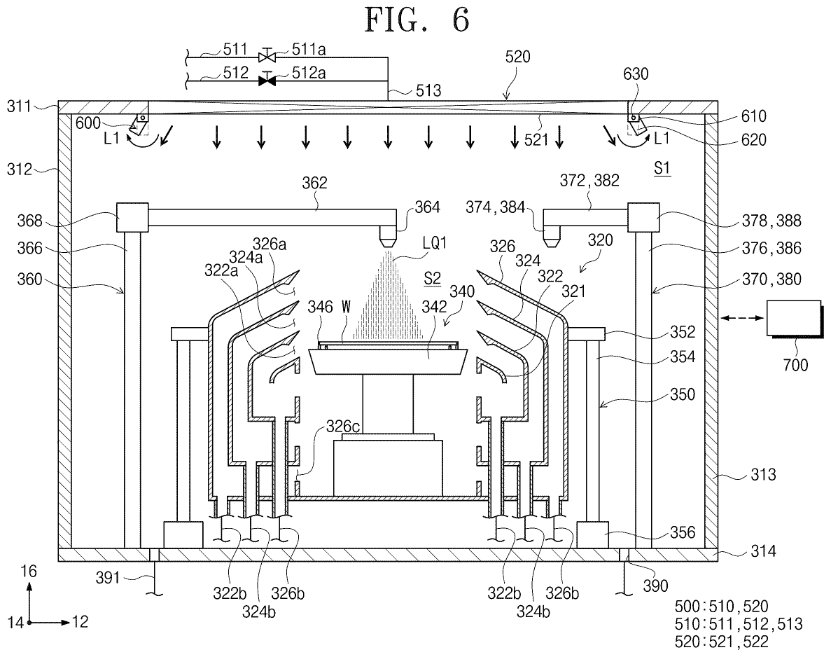

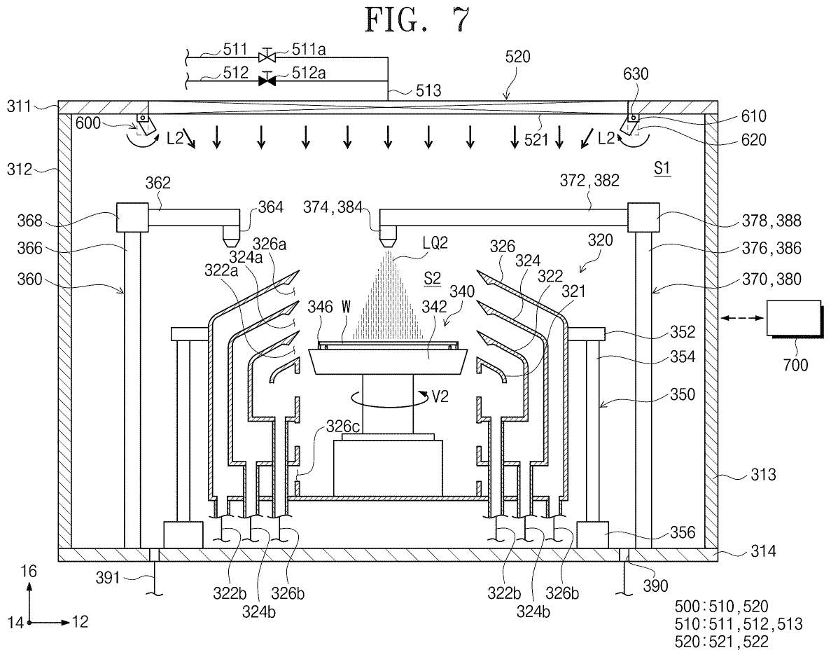

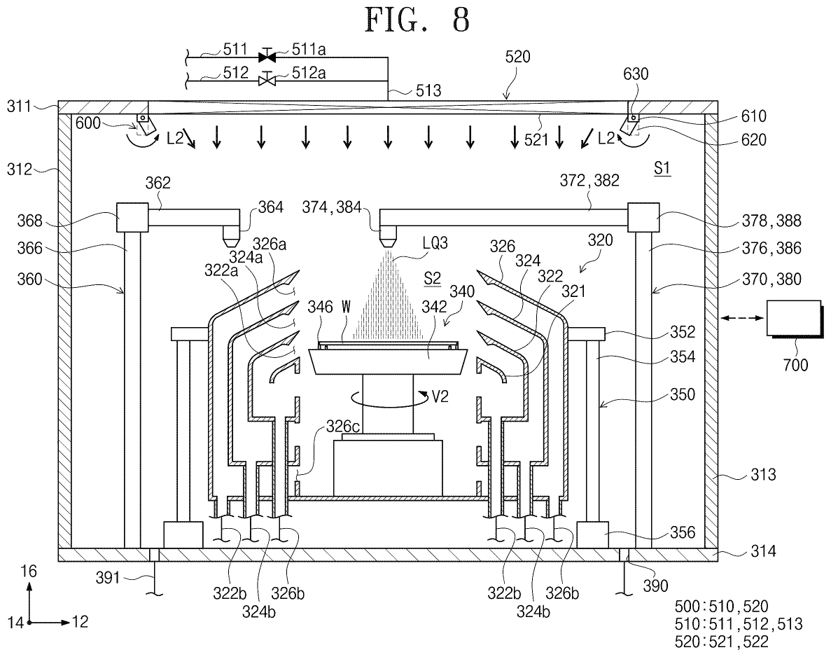

FIGS. 6 to 8 are diagrams illustrating a substrate processing method according to another embodiment of the present invention.

Referring to FIGS. 6 to 8, the controller 700 controls the airflow adjustment unit 600 based on the type of liquid supplied to the substrate when the substrate is processed. The substrate processing operation includes a first liquid treatment operation, a second liquid treatment operation, and a third liquid treatment operation.

The first liquid treatment operation is an operation of processing the substrate by supplying a first liquid to the substrate W, the second liquid treatment operation is an operation of processing the substrate by supplying a second liquid to the substrate W, and the third liquid treatment operation is an operation of processing the substrate by supplying a third liquid to the substrate W. The first liquid may be supplied by the first liquid supply unit 360, the second liquid may be supplied by the second liquid supply unit 370, and the third liquid may be supplied by the third liquid supply unit 380. In the first liquid treatment operation and the second liquid treatment operation, the first gas may be supplied in descending airflow by the fan unit 500, and in the third liquid treatment operation, the second gas may be supplied in the descending airflow.

The controller 700 may control the airflow adjustment unit 600 so that the airflow adjustment plate 620 is provided in the first mode in the first liquid treatment operation and the airflow adjustment plate 620 is provided in the second mode in the second liquid treatment operation and the third liquid treatment operation.

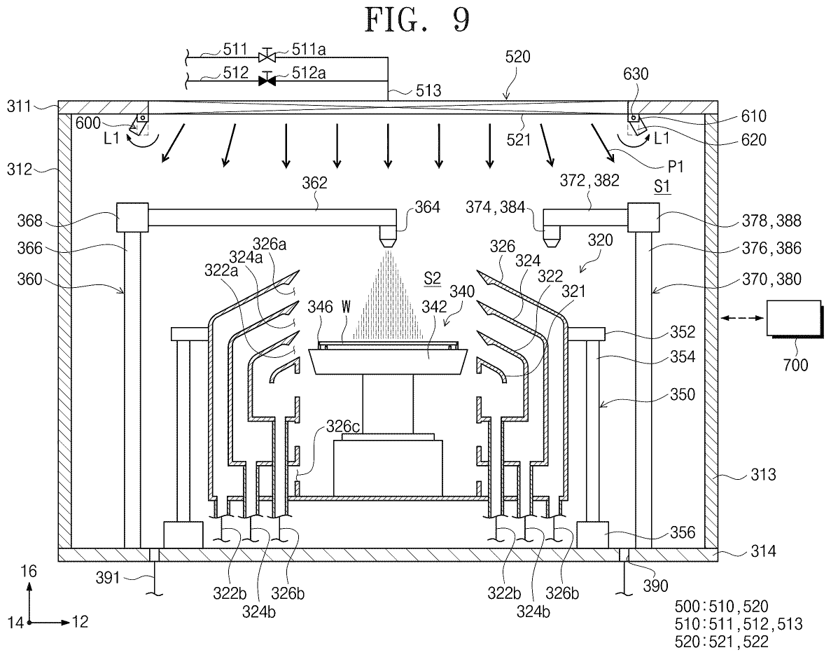

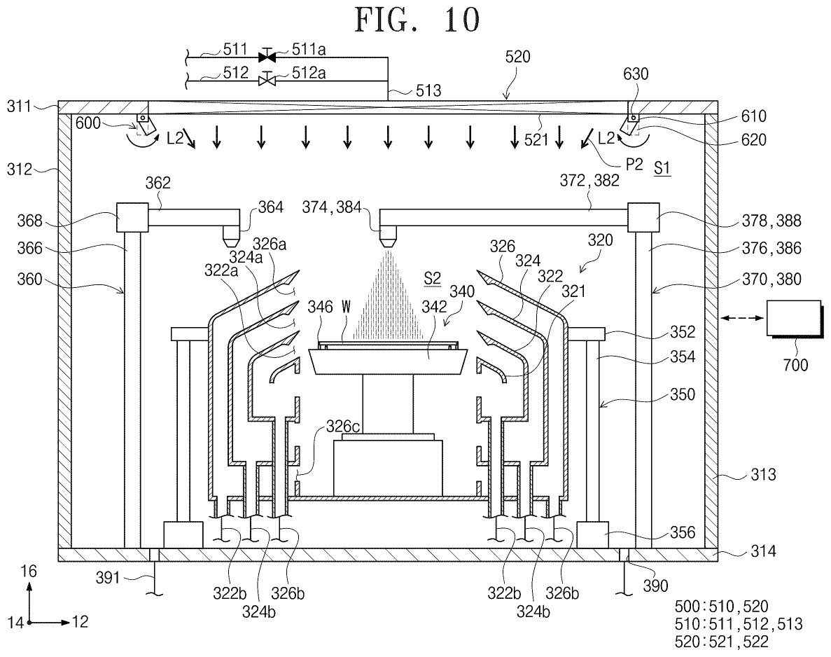

FIGS. 9 to 10 are diagrams illustrating a substrate processing method according to still another embodiment of the present invention.

Referring to FIGS. 9 to 10, the controller 700 controls the airflow adjustment unit 600 based on the operation mode of the fan unit 500 when processing the substrate. The operation mode of the fan unit 500 may include a normal mode in which the fan unit 500 supplies first gas to the inner space S1 as descending airflow while the substrate W is liquid-treated, and a low humidity mode in which the fan unit 500 supplies second gas to the inner space S1 as descending airflow while the substrate W is liquid-treated. The humidity of the second gas may be lower than the humidity of the first gas. When the fan unit 500 operates in a normal mode, a first liquid or a second liquid may be supplied onto the substrate W, and when the fan unit 500 operates in the low humidity mode, a third liquid may be supplied onto the substrate W. Also, when the fan unit 500 operates in the normal mode, the amount of descending airflow per unit time may be greater than the amount of descending airflow per unit time when the fan unit 500 operates in the low humidity mode.

The controller 700 may control the airflow adjustment unit 600 based on the operation mode of the fan unit 500. The controller 700 may control the airflow adjustment unit 600 so that the airflow adjustment plate 620 is provided in the first mode in the normal mode and the airflow adjustment plate 620 is provided in the second mode in the low humidity mode.

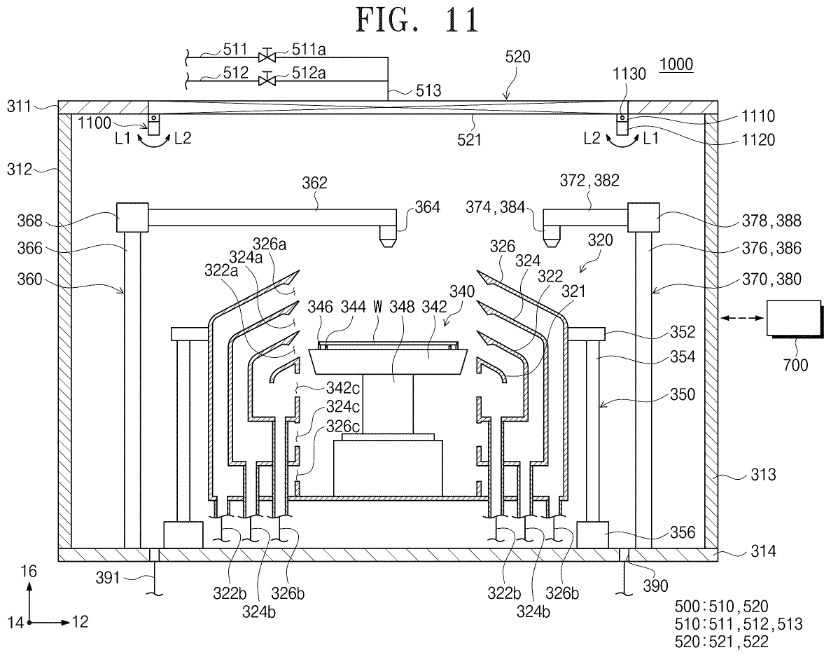

FIG. 11 is a plan view of a process chamber according to another embodiment of the present invention as viewed from the front.

Referring to FIG. 11, a process chamber 1000 includes a chamber body 310, a cup 320, a spin chuck 340, a lifting unit 350, a first liquid supply unit 360, a second liquid supply unit 370, an exhaust pipe 390, a fan unit 500, an airflow adjustment unit 1100, and a controller 700. The chamber body 310, the cup 320, the spin chuck 340, the lifting unit 350, the first liquid supply unit, the second liquid supply unit 370, the exhaust pipe 390, the fan unit 500, and the controller 700 are the same as the chamber body 310, the cup 320, the spin chuck 340, the lifting unit 350, the first liquid supply unit 360, the second liquid supply unit 370, the exhaust pipe 390, the fan unit 500, and the controller 700 illustrated in FIGS. 2 to 3. In FIG. 11, the airflow adjustment unit 1100 may be coupled to the bottom plate 521 of the fan filter 520.

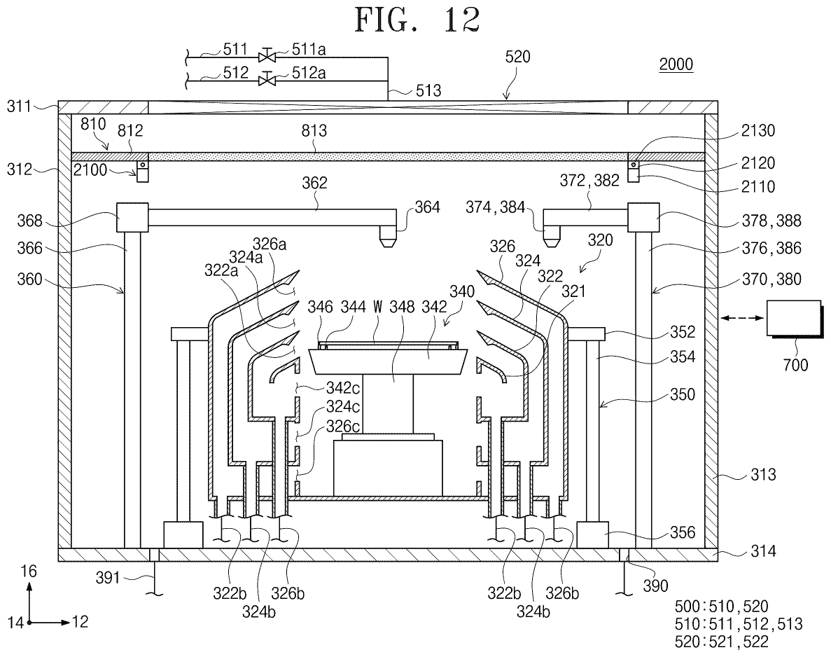

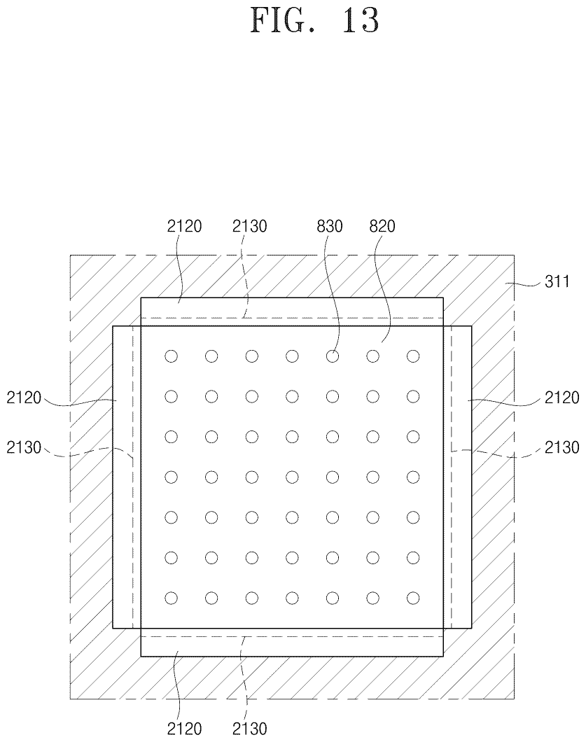

FIG. 12 is a top plan view of a process chamber according to still another embodiment of the present invention as viewed from the front. FIG. 13 is a top plan view of the process chamber of FIG. 12 viewed from below.

Referring to FIGS. 12 to 13, a process chamber 2000 includes a chamber body 310, a cup 320, a spin chuck 340, a lifting unit 350, a first liquid supply unit 360, a second liquid supply unit 370, an exhaust pipe 390, a fan unit 500, a perforated plate 800, an airflow adjustment unit 2100, and a controller 700.

The chamber body 310, the cup 320, the spin chuck 340, the lifting unit 350, the first liquid supply unit 360, the second liquid supply unit 370, the exhaust pipe 390, the fan unit 500, and the controller 700 are the same as those of the chamber body 310, the cup 320, the spin chuck 340, the lifting unit 350, the first liquid supply unit 360, the second liquid supply unit 370, the exhaust pipe 390, the fan unit 500, and the controller 700 of FIGS. 2 to 3.

The perforated plate 800 is provided below the fan unit 500. The perforated plate 800 includes a frame 810 and an airflow supply unit 820. The frame 810 is installed on opposite sidewalls 312 and 313 of the chamber body 310. The airflow supply unit 820 is provided in the center of the perforated plate 800. A hole 830 is formed on the lower surface of the airflow supply unit 820. The descending airflow supplied to the airflow supply unit 820 through the fan unit 500 is supplied to the inner space S1 through the hole 830.

The airflow adjustment unit 2100 may be coupled to the perforated plate 800. The airflow adjustment unit 2100 may include a plurality of airflow adjustment plates 2210 and a plurality of drivers 2220. When viewed from below, a plurality of airflow adjustment plates 2210 may be positioned to correspond to four sides of the airflow supply unit 820, respectively.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
a chamber body having an inner space;
a cup placed in the inner space and having a treatment space with an open top;
a spin chuck for supporting the substrate in the treatment space;
a liquid supply unit for supplying a treatment liquid to the substrate supported by the spin chuck;
a fan unit for providing descending airflow to the inner space;
an exhaust pipe for exhausting atmosphere in the inner space; and
an airflow adjustment unit for controlling a flow of the descending airflow supplied from the fan unit,
wherein the airflow adjustment unit includes:
an airflow adjustment plate provided in a first mode or a second mode to control a flow of descending airflow supplied from the fan unit; and
a driver for driving the airflow adjustment plate so that the airflow adjustment plate is provided in the first mode or the second mode, and
in the first mode, the airflow adjustment plate is configured to further diffuse the descending airflow discharged from the fan unit in the inner space than the airflow adjustment plate in the second mode.

2. The apparatus of claim 1, wherein in the second mode, the airflow adjustment plate is configured to further concentrate the descending airflow discharged from the fan unit in the treatment space than the airflow adjustment plate in the first mode.

3. The apparatus of claim 2, wherein the driver rotates the airflow adjustment plate so that the airflow adjustment plate is position-changed between the first mode and the second mode.

4. The apparatus of claim 3, wherein the fan unit includes a polygonal bottom plate through which airflow is discharged,
the airflow adjustment plates are provided at positions corresponding to sides of the bottom plate, respectively, and
each of the airflow adjustment plates is rotatably provided with an axis parallel to each of the corresponding sides as a rotation axis.

5. The apparatus of claim 4, wherein in the first mode, the airflow adjustment plate is inclined further downward in a direction toward an inner wall of the chamber body than the airflow adjustment plate in the second mode.

6. The apparatus of claim 5, wherein in the first mode, an angle between the airflow adjustment plate and the bottom plate is an obtuse angle, and
in the second mode, an angle between the airflow adjustment plate and the bottom plate is a right angle or an acute angle.

7. The apparatus of claim 4, wherein the airflow adjustment unit is coupled to the bottom plate.

8. The apparatus of claim 4, wherein when viewed from above, the airflow adjustment unit is coupled to an upper wall of the chamber body at a position adjacent to the bottom plate.

9. The apparatus of claim 2, wherein a perforated plate is provided below the fan unit in the inner space, and
the airflow adjustment unit is coupled to the perforated plate.

10. The apparatus of claim 2, wherein the liquid supply unit includes:
a first liquid supply unit for supplying a first liquid;
a second liquid supply unit for supplying a second liquid different from the first liquid; and
a controller, and
the controller is configured to
control the liquid supply unit so that a first liquid treatment operation of processing the substrate by supplying the first liquid and a second liquid treatment operation of processing the substrate by supplying the second liquid are sequentially performed, and
control the driver so that the airflow adjustment plate maintains a first mode during the first liquid treatment operation and the airflow adjustment plate maintains a second mode during the second liquid treatment operation.

11. The apparatus of claim 10, wherein the first liquid is a liquid that does not contain an acid component, and the second liquid is a liquid that contains an acid component.

12. The apparatus of claim 2, wherein the fan unit includes:
a normal mode in which the first gas is supplied in the descending airflow during the liquid treatment of the substrate; and
a low humidity mode in which second gas having a lower humidity than the first gas is supplied in the descending airflow during the liquid treatment of the substrate, and
the airflow adjustment plate is provided in the first mode in the normal mode and is provided in the second mode in the low humidity mode.

13. The apparatus of claim 2, comprising:
a first processing operation of processing the substrate while rotating the substrate at a first speed, and
a second processing operation of processing the substrate while rotating the substrate at a second speed slower than the first speed,
wherein the airflow adjustment plate is provided in the first mode in the first processing operation and is provided in the second mode in the second processing operation.

14. An apparatus for processing a substrate, the apparatus comprising:
a chamber body having an inner space;
a cup placed in the inner space and having a treatment space with an open top;
a spin chuck for supporting the substrate in the treatment space;
a liquid supply unit for supplying a treatment liquid to the substrate supported by the spin chuck;
a fan unit for providing descending airflow to the inner space;
an exhaust pipe for exhausting atmosphere in the inner space; and
an airflow adjustment unit for controlling a flow of descending airflow supplied from the fan unit,
wherein the airflow adjustment unit includes:
an airflow adjustment plate disposed between the fan unit and the cup and controlling a flow of descending airflow supplied from the fan unit; and
a driver for rotating the airflow adjustment plate so that an angle between a bottom plate of the fan unit and the airflow adjustment plate is changed.

15. The apparatus of claim 14, wherein the bottom plate is provided in a rectangular shape including four sides,
the airflow adjustment plate is disposed on each of the four sides, and
each of the airflow adjustment plates is rotatably provided with an axis parallel to the corresponding side of the four sides as a rotation axis.

16. The apparatus of claim 14, wherein the airflow adjustment unit is coupled to the fan unit.

17. The apparatus of claim 14, wherein the airflow adjustment unit is coupled to an upper wall of the chamber body.

18. The apparatus of claim 13, further comprising:
a perforated plate,
wherein the airflow adjustment unit is coupled to a lower surface of the perforated plate.

19. An apparatus for processing a substrate, the apparatus comprising:
a chamber body having an inner space;
a cup placed in the inner space and having a treatment space with an open top;
a spin chuck for supporting the substrate in the treatment space;
a liquid supply unit for supplying a treatment liquid to the substrate supported by the spin chuck;
a fan unit for providing descending airflow to the inner space;
an exhaust pipe for exhausting atmosphere in the inner space; and
an airflow adjustment unit for controlling a flow of descending airflow supplied from the fan unit,
wherein the airflow adjustment unit includes:
an airflow adjustment plate provided in a first mode or a second mode to control a flow of descending airflow supplied from the fan unit; and
a driver for driving the airflow adjustment plate so that the airflow adjustment plate is provided in the first mode or the second mode, and
in the first mode, the airflow adjustment plate is configured to further diffuse the descending airflow discharged from the fan unit in the inner space than the airflow adjustment plate in the second mode,
in the second mode, the airflow adjustment plate is configured to further concentrate the descending airflow discharged from the fan unit in the treatment space than the airflow adjustment plate in the first mode,
the driver rotates the airflow adjustment plate so that the airflow adjustment plate is position-changed between the first mode and the second mode,
the fan unit includes a polygonal bottom plate through which airflow is discharged,
the airflow adjustment plates are provided at positions corresponding to sides of the bottom plate, respectively,
each of the airflow adjustment plates is rotatably provided with an axis parallel to each of the corresponding sides as a rotation axis, and
in the first mode, the airflow adjustment plate is inclined further downward in a direction toward an inner wall of the chamber body than the airflow adjustment plate in the second mode.

20. The apparatus of claim 19, wherein the liquid supply unit includes:
a first liquid supply unit for supplying a first liquid;
a second liquid supply unit for supplying a second liquid different from the first liquid; and
a controller, and
the controller is configured to
control the liquid supply unit so that a first liquid treatment operation of processing the substrate by supplying the first liquid and a second liquid treatment operation of processing the substrate by supplying the second liquid are sequentially performed, and
control the driver so that the airflow adjustment plate maintains a first mode during the first liquid treatment operation and the airflow adjustment plate maintains a second mode during the second liquid treatment operation, and
the first liquid is a liquid that does not contain an acid component, and the second liquid is a liquid that contains an acid component.
